(19) United States
(12) Patent Application Publication
(10) Pub. No.: US 2007/0045792 A1
(43) Pub. Date: Mar. 1, 2007

(54) SEMICONDUCTOR DEVICE AND SEMICONDUCTOR PACKAGE

(75) Inventor: Kenji FUCHINOUE, Miyazaki (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/458,687

(22) Filed: Jul. 20, 2006

(30) Foreign Application Priority Data
Jul. 29, 2005 (JP) 2005-219847

(51) Int. Cl. H01L 23/495

(52) U.S. Cl. 257/676

(57) ABSTRACT

The semiconductor device includes a chip, a sealing resin for sealing the chip, which includes a first lateral side and a second lateral side, both of which are located adjacent to each other, and a plurality of leads that protrude from different positions on the first lateral side. The positions on the first lateral side have different distances from the second lateral side, and the protruding distances of the plurality of the leads are set to be longer as their positions on the first lateral side are located nearer to the second lateral side. The semiconductor device is mounted on a mounting board through a second lateral side of the sealing resin.

### BACKGROUND OF THE INVENTION

1. Field of the Invention

The present invention relates to a semiconductor device and a semiconductor package. In particular, the present invention relates to a lead structure of a semiconductor device. A semiconductor package that is required to be mounted on a surface of a mounting board in a specific direction, and a method of mounting the semiconductor device.

2. Background of the Invention

A semiconductor device in which a three-axis sensor represented by a Hall element is embedded is known as an example of a semiconductor device that is required to be mounted on a surface of a mounting board in a specific direction. The semiconductor device has a structure in which a three-axis sensor is packaged with a sealing resin. For example, when the Hall element is mounted on the mounting board, there is a possibility that the direction of the magnetic field detection surface of the Hall element may have influence on the sensitivity thereof.

Japan Registered Utility Model Publication JP-U-3061660 (q.v., paragraph 0004 and FIG. 1) discloses a structure in which a lead frame in a hall element package sealed by a resin mold comprises an input/output terminal and a pellet mounting surface, and is configured so that the input/output terminal frame and the pellet mounting surface are arranged to form a predetermined angle and not in parallel with each other, so that the magnetic detection surface and the main magnetic flux will become orthogonal with each other when the Hall element is mounted on a motor.

In order to apply the aforementioned conventional art to a semiconductor device, there is a prerequisite that the lead frame should include an input/output terminal and a pellet mounting surface. However, a typical semiconductor package, that is, a typical semiconductor device, has a normal lead that linearly extends outward from a lateral side of the sealing resin. Therefore, if this kind of typical semiconductor package, that is, a typical semiconductor device, is mounted on a mounting board in a face-up or face-down state according to the conventional mounting method, there will be a problem in that the semiconductor device will be mounted on a surface of the mounting board in a direction that is different from the specific direction originally intended.

It is therefore an object of the present invention to provide an improved semiconductor device, an improved semiconductor package, and an improved mounting method thereof which are capable of resolving the above-described problem.

Furthermore, it is an another object of the present invention to provide a lead structure of a semiconductor device which is required to be mounted on a surface of a mounting board in a specific direction, and a mounting method for the semiconductor device.

This invention addresses this need in the art as well as other needs, which will become apparent to those skilled in the art from this disclosure.

### SUMMARY OF THE INVENTION

According to a first aspect of the present invention, a semiconductor device comprises a chip, a sealing resin for sealing the chip, which includes a first lateral side and a second lateral side, both of which are located adjacent to each other, and a plurality of first leads that protrude from different positions on the first lateral side. Here, the positions of the first leads on the first lateral side have different distances from the second lateral side, and the protruding distances of the plurality of first leads are set to be longer as the positions thereof are located nearer to the second lateral side.

According to a second aspect of the present invention, a semiconductor package comprises a semiconductor device that comprises a chip, a sealing resin for sealing the chip, which includes a first lateral side and a second lateral side, both of which are located adjacent to each other, and a plurality of first leads that protrude from different positions on the first lateral side of the sealing resin, and a mounting board on which the second lateral side of the sealing resin in the semiconductor device is fixed.

According to the present invention, the plurality of first leads protrude from different positions on the first lateral side. The positions of the first leads on the first lateral side have different distances from the second lateral side. In addition, the protruding distances of the plurality of first leads are set to be longer as their positions on the first lateral side are located nearer to the first lateral side. This lead structure makes it possible to mount the semiconductor device on the mounting board so that not the back side, but the lateral side, of the sealing resin faces the mounting board. By having the semiconductor device mounted on the mounting board so that the lateral side of the sealing resin faces downward, the upper surface of the chip sealed by the sealing resin will face in a direction parallel with the surface of the mounting board. For example, the present invention is effective and useful especially when the chip has an element that is required to face in a specific direction with respect to the surface of the mounting board at the time when the semiconductor device is mounted on the mounting board, typically a heretofore known three-axis sensor, or more specifically, a Hall element.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a lateral view of a semiconductor device in accordance with a particular embodiment of the present invention;

FIG. 2 is a top view of the semiconductor device shown in FIG. 1;

FIG. 3 is a perspective view of the semiconductor device shown in FIG. 1; and

FIG. 4 is a top view of the semiconductor device mounted on a mounting board shown in FIGS. 1 to 3.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### Particular Embodiment

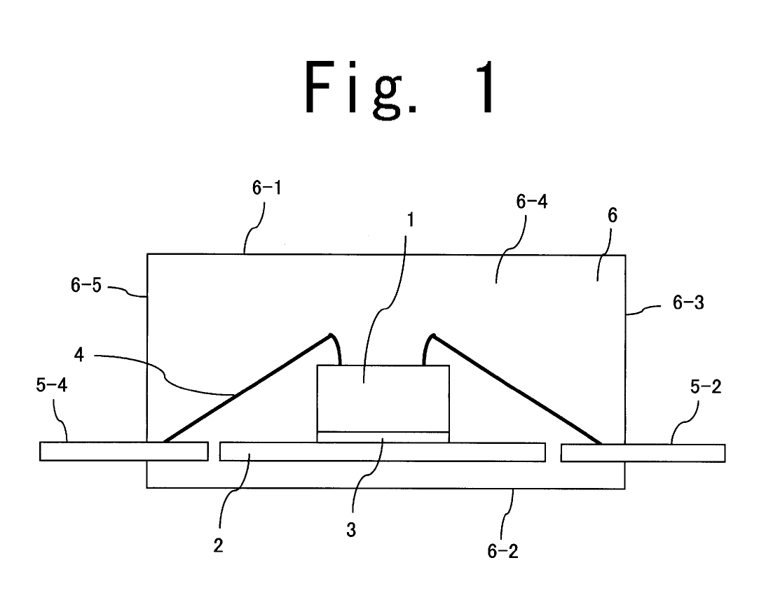

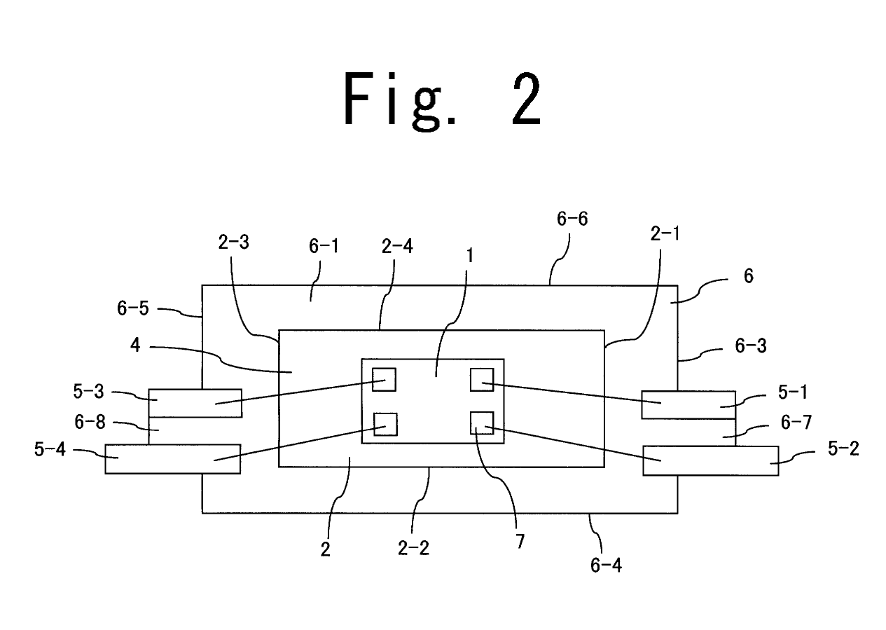

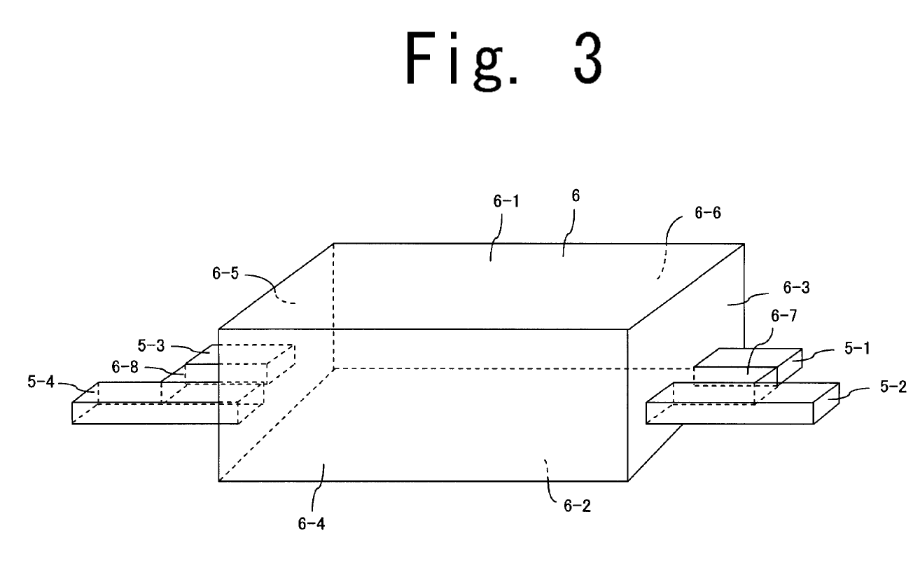

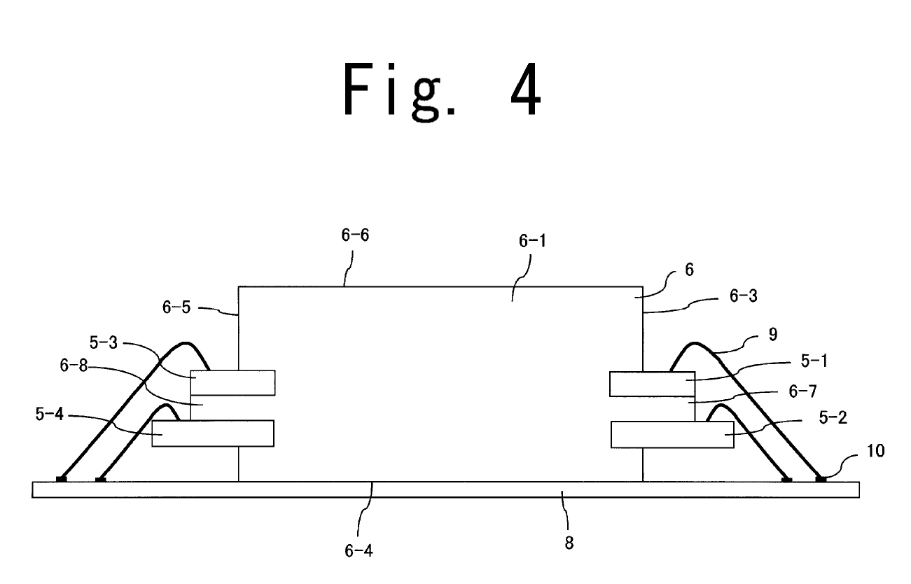

A particular embodiment of the present invention provides a semiconductor device that is required to be mounted on a surface of a mounting board in a specific direction and has a new lead structure, and a mounting method thereof. FIG. 1 is a lateral view of the semiconductor device in accordance with this embodiment of the present invention. FIG. 2 is a top view of the semiconductor device shown in FIG. 1. FIG. 3 is a perspective view of the semiconductor device shown in FIG. 1. FIG. 4 is a top view of the semiconductor device mounted on the mounting board shown in FIGS. 1 to 3.

As shown in FIGS. 1 to 3, the semiconductor device in accordance with this embodiment of the present invention comprises a die pad 2, a chip 1, first to fourth leads 5-1,5-2, 5-3, and 5-4, and a sealing resin 6.

The chip 1 is glued on the die pad 2 by means of an adhesive 3. Multiple electrode pads 7 are arranged on a peripheral marginal region of an upper surface of the chip 1. Although four electrode pads 7 are shown in FIG. 2 for the convenience of explanation, the number of the electrode pads 7 is not necessarily limited to four. In this embodiment, however, for the convenience of explanation, the semiconductor device in which four electrode pads 7 are formed on the upper surface of the chip 1 will be explained as an example. The chip 1 may be any type of chip as long as it has a heretofore known element that is sealed by the sealing resin 6, electrically coupled to at least one lead, and has a specific function. For example, the chip 1 may have an element that is required to face in a specific direction with respect to a surface of a mounting board 8 when mounted on the mounting board 8. A typical example of the element that is required to face in a specific direction with respect to a surface of the mounting board 8 is a heretofore known three-axis sensor, more specifically, a Hall element.

An outer periphery of the die pad 2 is defined by four lateral sides, that is, first to fourth lateral sides 2-1, 2-2, 2-3, and 2-4. In this configuration, the first and third lateral sides 2-1 and 2-3 are located opposite to each other, and the second and fourth lateral sides 2-2 and 2-4 are located opposite to each other. In addition, the first and second lateral sides 2-1 and 2-2 are adjacently located, and the first and fourth lateral sides 2-1 and 2-4 are adjacently located. The second and third lateral sides 2-2 and 2-3 are adjacently located, and the third and fourth lateral sides 2-3 and 2-4 are adjacently located. The die pad 2 has a heretofore known structure.

The sealing resin 6 seals the die pad 2, the chip 1, and the inner portion of the first to fourth leads 5-1, 5-2, 5-3, and 5-4. The sealing resin 6 has a front surface 6-1 and a back surface 6-2, both of which are parallel with a surface of the die pad 2. In addition, the sealing resin 6 has first to fourth lateral sides 6-3, 6-4, 6-5, and 6-6, each of which is perpendicular to a surface of the die pad 2. The first and third lateral sides 6-3 and 6-5 are located opposite to each other and at the same time extend in parallel with each other. The second and fourth lateral sides 6-4 and 6-6 are located opposite to each other and at the same time extend in parallel with each other. The first lateral side 6-3 is located adjacent to the second lateral side 6-4. The second lateral side 6-4 is located adjacent to the third lateral side 6-5. The third lateral side 6-5 is located adjacent to the fourth lateral side 6-6. The sealing resin 6 can be made of a heretofore known sealing resin material.

Although four leads are shown in FIGS. 2 to 4 for the convenience of explanation, the number of the leads is not necessarily limited to four. In this embodiment, however, for the convenience of explanation, the semiconductor device on which four leads are formed will be explained as an example.

The first and second leads 5-1 and 5-2 extend outward from a position that is outside of the first lateral side 2-1 of the die pad 2 and separated from the first lateral side 2-1 by a predetermined space. The first and second leads 5-1 and 5-2 extend in the vertically outside direction from the first lateral side 2-1 of the die pad 2 and are in the same plane as the die pad 2. In other words, as shown in FIG. 1, the first and second leads 5-1 and 5-2 extend in the same plane as the die pad 2.

The inner portions of the first lead 5-1 and the second lead 5-2, respectively, are sealed by the sealing resin 6. Accordingly, the outer portions of the first lead 5-1 and the second lead 5-2, respectively, protrude outward from the first lateral side 6-3 of the sealing resin 6.

The distance between the inner edge of the first lead 5-1 and the first lateral side 2-1 of the die pad 2 may be the same as the distance between the inner edge of the second lead 5-2 and the first lateral side 2-1 of the die pad 2. In other words, the inner edge of the first lead 5-1 and the inner edge of the second lead 5-2 may be arranged on the same line parallel with the first lateral side 2-1 of the die pad 2. In addition, the second lead 5-2 has a length longer than that of the first lead 5-1 in the direction perpendicular to the first lateral side 2-1 of the die pad 2. Therefore, the outer edge of the second lead 5-2 is positioned to the outside of the outer edge of the first lead 5-1. In other words, the length of the portion of the second lead 5-2 that protrudes from the first lateral side 6-3 of the sealing resin 6 is longer than that of the portion of the first lead 5-1 that protrudes from the first lateral side 6-3 of the sealing resin 6 in a direction perpendicular to the first lateral side 2-1 of the die pad 2. That is to say, the second lead 5-2 extends further outward than the outer edge of the first lead 5-1. A first extended portion 6-7 of the sealing resin 6 extends up to the outer edge of the first lead 5-1.

The distance between the inner edge of the first lead 5-1 and the first lateral side 2-1 of the die pad 2 may be different from the distance between the inner edge of the second lead 5-2 and the first lateral side 2-1 of the die pad 2. Even in such configuration, the length of the portion of the second lead 5-2 that protrudes from the first lateral side 6-3 of the sealing resin 6 is longer than that of the portion of the first lead 5-1 that protrudes from the first lateral side 6-3 of the sealing resin 6.

The first and second leads 5-1 and 5-2 extend in parallel with each other, and at the same time, they are separated from each other by a predetermined space. The first extended portion 6-7 of the sealing resin 6 is interposed between the portions of the first and second leads 5-1 and 5-2 that protrude from the first lateral side 6-3 of the sealing resin 6. The first extended portion 6-7 may be formed so as to be integrated with the sealing resin 6, or may be formed so as to be separated from the sealing resin 6. The first extended portion 6-7 adds to the mechanical strength of the portions of the first and second leads 5-1 and 5-2 that protrude from the first lateral side 6-3 of the sealing resin 6. As described above, the second lead 5-2 extends further outward than the outer edge of the first lead 5-1. Therefore, the first extended portion 6-7 can extend up to the outer edge of the first lead 5-1. In this case, the first extended portion 6-7 of the sealing resin 6 is not located adjacent to the second lead 5-2 that extends further outward than the outer edge of the first lead 5-1. That is to say, the second lead 5-2 extends further outward than the outer edge of the first lead 5-1 and includes a portion to which the first extended portion 6-7 of the sealing resin 6 is not adjacently located. As described above, the first extended portion 6-7 of the sealing resin 6 is provided for the purpose of adding to the mechanical strength of the protruding portions of the first and second leads 5-1 and 5-2. Therefore, the first extended portion 6-7 is not necessarily required to extend up to the outer edge of the first lead 5-1. In addition, if it is not necessary to add to the mechanical strength of the protruding portions of the first and second leads 5-1 and 5-2, the sealing resin 6 does not have to include the first extended portion 6-7.

The third and fourth leads 5-3 and 5-4 may be configured to have a structure that is asymmetrical to or symmetrical to the first and second leads 5-1 and 5-2. A case in which the third and fourth leads 5-3 and 5-4 have a structure symmetrical to the first and second leads 5-1 and 5-2 will be hereinafter explained.

The third and fourth leads 5-3 and 5-4 extend outward from a position that is outside of the third lateral side of the die pad 2 and separated from the third lateral side by a predetermined space. The third and fourth leads 5-3 and 5-4 extend in the vertically outside direction from the third lateral side 2-3 of the die pad 2 and are in the same plane as the die pad 2. In other words, as shown in FIG. 1, the third and fourth leads 5-3 and 5-4 extend in the same plane as the die pad 2. As described above, the first and second leads 5-1 and 5-2 also extend in the same plane as the die pad 2. Accordingly, the first to fourth leads 5-1, 5-2, 5-3, and 5-4 extend in the same plane as the die pad 2.

The inner portions of the third lead 5-3 and the fourth lead 5-4, respectively, are sealed by the sealing resin 6. Accordingly, the outer portions of the third lead 5-3 and the fourth lead 5-4, respectively, protrude outward from the third lateral side 6-5 of the sealing resin 6.

The distance between the inner edge of the third lead 5-3 and the third lateral side 2-3 of the die pad 2 may be the same as the distance between the inner edge of the fourth lead 5-4 and the third lateral side 2-3 of the die pad 2. In other words, the inner edge of the third lead 5-3 and the inner edge of the fourth lead 5-4 may be arranged on the same line and parallel with the third lateral side 2-3 of the die pad 2. In addition, the fourth lead 5-4 has a length longer than that of the third lead 5-3 in the direction perpendicular to the third lateral side 2-3 of the die pad 2. Therefore, the outer edge of the fourth lead 5-4 is positioned to the outside of the outer edge of the third lead 5-3. In other words, the length of the portion of the fourth lead 5-4 that protrudes from the third lateral side 6-5 of the sealing resin 6 is longer than that of the portion of the third lead 5-3 that protrudes from the third lateral side 6-5 of the sealing resin 6 in a direction perpendicular to the third lateral side 2-3 of the die pad 2. That is to say, the fourth lead 5-4 extends further outward than the outer edge of the third lead 5-3. A second extended portion 6-8 of the sealing resin 6 extends up to the outer edge of the third lead 5-3.

The distance between the inner edge of the third lead 5-3 and the third lateral side 2-3 of the die pad 2 may be different from the distance between the inner edge of the fourth lead 5-4 and the third lateral side 2-3 of the die pad 2. Even in such configuration, the length of the portion of the fourth lead 5-4 that protrudes from the third lateral side 6-5 of the sealing resin 6 is longer than that of the portion of the third lead 5-3 that protrudes from the third lateral side 6-5 of the sealing resin 6.

The third and fourth leads 5-3 and 5-4 extend in parallel with each other, and at the same time, they are separated from each other by a predetermined space. The second extended portion 6-8 of the sealing resin 6 is interposed between the portions of the third and fourth leads 5-3 and 5-4 that protrude from the third lateral side 6-5 of the sealing resin 6. The second extended portion 6-8 may be formed so as to be integrated with the sealing resin 6, or may be formed so as to be separated from the sealing resin 6. The second extended portion 6-8 adds to the mechanical strength of the portions of the third and fourth leads 5-3 and 5-4 that protrude from the third lateral side 6-5 of the sealing resin 6. As described above, the fourth lead 5-4 extends further outward than the outer edge of the third lead 5-3. Therefore, the second extended portion 6-8 can extend up to the outer edge of the third lead 5-3. In this case, the second extended portion 6-8 of the sealing resin 6 is not located adjacent to the fourth lead 5-4 that extends further outward than the outer edge of the third lead 5-3. That is to say, the fourth lead 5-4 extends further outward than the outer edge of the third lead 5-3, and includes a portion to which the second extended portion 6-8 of the sealing resin 6 is not adjacently located. As described above, the second extended portion 6-8 of the sealing resin 6 is provided for the purpose of adding to the mechanical strength of the protruding portions of the third and fourth leads 5-3 and 5-4. Therefore, the second extended portion 6-8 is not necessarily required to extend up to the outer edge of the third lead 5-3. In addition, if it is not necessary to add to the mechanical strength of the protruding portions of the third and fourth leads 5-3 and 5-4, the sealing resin 6 does not have to include the second extended portion 6-8.

Although in general, multiple leads extend within the same plane, as described above, the first to fourth leads 5-1, 5-2, 5-3, and 5-4 may not necessarily extend within the same plane.

The first to fourth leads 5-1, 5-2, 5-3, and 5-4, respectively, can be made of a heretofore known lead material.

As described above, multiple electrode pads 7 are arranged in the peripheral region on the upper surface of the chip 1. The inner portions of the first to fourth leads 5-1, 5-2, 5-3, and 5-4 are sealed by the sealing resin 6. Each of the inner portions is electrically coupled to each of the electrode pads 7 through a first bonding wire 4. As shown in FIG. 1, the first bonding wire 4 is sealed by the aforementioned sealing resin 6.

In general, the aforementioned semiconductor device is mounted on the mounting board 8 so that the back surface 6-2 of the sealing resin 6 faces the mounting board 8. According to the present invention, the semiconductor device may be mounted on the mounting board 8 so that the back surface 6-2 of the sealing resin 6 faces the mounting surface of the mounting board 8. However, there might be a case in which the semiconductor device is required to be mounted on the mounting board 8 so that the upper surface of the chip 1 on which the electrode pads 7 are formed is arranged to be perpendicular to the mounting surface of the mounting board 8, depending on the type of element included in the chip 1. In such configuration, as shown in FIG. 4, the semiconductor device is mounted on the mounting board 8 so that the second lateral side 6-4 of the sealing resin 6 faces the mounting surface of the mounting board 8. The fourth lateral side 6-6 of the sealing resin 6 of the semiconductor device mounted on the mounting board 8 faces upward, and the second lateral side 6-4 faces downward. Therefore, the first lead 5-1 will be positioned above the second lead 5-2, and the third lead 5-3 will be positioned above the fourth lead 5-4. In other words, the first and second leads 5-1 and 5-2 will extend within a plane perpendicular to the surface of the mounting board 8. Furthermore, the third and fourth leads 5-3 and 5-4 will extend within a plane perpendicular to the surface of the mounting board 8. The first lead 5-1 will have an outer portion that protrudes outward from the first lateral side 6-3 of the sealing resin 6 and the protruding length thereof will be longer than that of the second lead 5-2. The upper surface of the outer portion of the first lead 5-1 will be exposed without being sealed by the first extended portion 6-7. The third lead 5-3 will have an outer portion that protrudes outward from the third lateral side 6-3 of the sealing resin 6 and the protruding length thereof will be longer than that of the fourth lead 5-4. The upper surface of the outer portion of the third lead 5-3 will be exposed without being sealed by the second extended portion 6-8.

Four foot patterns (connecting members) 10 are formed on the peripheral region on the mounting board 8. Each of the four foot patterns 10 is coupled to each of the exposed surface of the first to fourth leads 5-1, 5-2, 5-3, and 5-4 through a second bonding wire 9. As described above, the second lead 5-2 protrudes outward from the first lateral side 6-3 of the sealing resin 6, and the length of the protruding portion (i.e., the outer portion) thereof is longer than that of the protruding portion (i.e., the outer portion) of the first lead 5-1. In addition, an upper surface of the outer portion of the second led 5-2 is exposed without being sealed by the first extended portion 6-7 of the sealing resin 6. Therefore, the upper surface of the outer portion of the second lead 5-2 can be electrically coupled to the foot pattern 10 through the second bonding wire 9. In the same way, the fourth lead 5-4 protrudes outward from the third lateral side 6-5 of the sealing resin 6, and the length of the protruding portion (i.e., the outer portion) thereof is longer than that of the protruding portion (i.e., the outer portion) of the third lead 5-3. In addition, an upper surface of the outer portion of the fourth lead 5-4 is exposed without being sealed by the second extended portion 6-8 of the sealing resin 6. Therefore, the upper surface of the outer portion of the fourth lead 5-4 can be electrically coupled to the foot pattern 10 through the second bonding wire 9.

As is the case in the conventional art, if the protruding portions of the first and second leads 5-1 and 5-2 have the same length, the first lead 5-1 will be located above the second lead 5-2 so that the first lead 5-1 overlaps the second lead 5-2. Therefore, it will be difficult for the second lead 5-2 to be electrically coupled to the foot pattern 10 through the second bonding wire 9. Furthermore, if the protruding portions of the third and fourth leads 5-3 and 5-4 have the same length, the third lead 5-3 will be located above the fourth lead 5-4 so that the third lead 5-3 overlaps the fourth lead 5-4. Therefore, it will be difficult for the fourth lead 5-4 to be electrically coupled to the foot pattern 10 through the second bonding wire 9.

However, according to this embodiment of the present invention, the second lead 5-2 protrudes outward from the first lateral side 6-3 of the sealing resin 6, and the length of the protruding portion (i.e., the outer portion) of the second lead 5-2 is longer than that of the protruding portion (i.e., the outer portion) of the first lead 5-1. In addition, the upper portion of the outer portion of the second lead 5-2 is exposed without being sealed by the first extended portion 6-7 of the sealing resin 6. Therefore, the upper surface of the outer portion of the second lead 5-2 can be electrically coupled to the foot pattern 10 through the second bonding wire 9. In the same way, the fourth lead 5-4 protrudes outward from the third lateral side of the sealing resin 6, and the length of the protruding portion (i.e., the outer portion) of the fourth lead 5-4 is longer than that of the protruding portion (i.e., the outer portion) of the third lead 5-3. In addition, the upper surface of the outer portion of the fourth lead 5-4 is exposed without being sealed by the second extended portion 6-8 of the sealing resin 6. Therefore, the upper surface of the outer portion of the fourth lead 5-4 can be electrically coupled to the foot pattern 10 through the second bonding wire 9.

The aforementioned lead structure makes it possible to mount the semiconductor device on the mounting board 8 so that not the back surface 6-2, but the second lateral side 6-4 of the sealing resin 6, faces the mounting surface of the mounting board 8. By having the semiconductor device mounted on the mounting board 8 so that the second lateral side 6-4 of the sealing resin 6 faces downward, the upper surface of the chip 1 that is sealed by the sealing resin 6, that is, the surface on which the electrode pads 7 are formed, will face in a direction parallel with the surface of the mounting board 8. For example, the present invention is effective and useful especially when the chip 1 has an element that is required to face in a specific direction with respect to the mounting surface of the mounting board 8 when the semiconductor device is mounted on the mounting board 8, typically a heretofore known three-axis sensor, or more specifically, a Hall element.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2005-219847. The entire disclosure of Japanese Patent Application No. 2005-219847 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor device, comprising:
a chip;
a sealing resin for sealing the chip, the sealing resin comprising a first lateral side and a second lateral side located adjacent to each other; and
a plurality of first leads that protrude from different positions on the first lateral side, the positions on the first lateral side having different distances from the second lateral side, and the protruding distances of the plurality of first leads being set to be longer as the positions thereof on the first lateral side are located nearer to the second lateral side.

2. The semiconductor device according to claim 1, wherein the plurality of first leads are arranged to extend within the same plane perpendicular to the first lateral side and the second lateral side.

3. The semiconductor device according to claim 1, wherein the sealing resin further comprises one or more first extended portions that extend outward from the first lateral side and are arranged between the plurality of first leads.

4. The semiconductor device according to claim 1, further comprising one or more first reinforcement resins that extend outward from the first lateral side and are arranged between the plurality of first leads.

5. The semiconductor device according to claim 1, further comprising a plurality of second leads that protrude from different positions on a third lateral side that is located adjacent to the second lateral side and opposite to the first lateral side, the positions on the third lateral side having different distances from the second lateral side, and the protruding distances of the plurality of second leads being set to be longer as the positions thereof on the third lateral side are located nearer to the second lateral side.

6. The semiconductor device according to claim 5, wherein the plurality of second leads are arranged to extend within the same plane perpendicular to the third lateral side and the second lateral side.

7. The semiconductor device according to claim 5, wherein the sealing resin further comprises one or more second extended portions that extend outward from the third lateral side and are arranged between the plurality of second leads.

8. The semiconductor device according to claim 5, further comprising one or more second reinforcement resins that extend outward from the third lateral side and are arranged between the plurality of second leads.

9. The semiconductor device according to claim 1, further comprising a mounting board on which the second lateral side of the sealing resin is mounted and that is electrically coupled to the plurality of first leads.

10. A semiconductor package, comprising:
a semiconductor device, comprising:
a chip;
a sealing resin for sealing the chip, the sealing resin comprising a first lateral side and a second lateral side located adjacent to each other; and
a plurality of first leads that protrude from different positions on the first lateral side of the sealing resin; and
a mounting board on which the second lateral side of the sealing resin in the semiconductor device is fixed.

11. The semiconductor package according to claim 10, wherein the plurality of first leads protrude from different positions on the first lateral side, the positions on the first lateral side having different distances from the second lateral side, and the protruding distances of the plurality of first leads being set to be longer as the positions thereof on the first lateral side are located nearer to the second lateral side.

12. The semiconductor package according to claim 10, wherein the plurality of first leads are arranged to extend within the same plane perpendicular to the first lateral side and the second lateral side.

13. The semiconductor package according to claim 11, wherein the sealing resin further comprises one or more first extended portions that extend outward from the first lateral side and are arranged between the plurality of first leads.

14. The semiconductor package according to claim 10, further comprising one or more first reinforcement resins that extend outward from the first lateral side and are arranged between the plurality of first leads.

15. The semiconductor package according to claim 10, further comprising a plurality of second leads that protrude from different positions on a third lateral side that is located adjacent to the second lateral side and opposite to the first lateral side, the positions on the third lateral side having different distances from the second lateral side, and the protruding distances of the plurality of second leads being set to be longer as the positions thereof on the third lateral side are located nearer to the second lateral side.

16. The semiconductor package according to claim 15, wherein the plurality of second leads are arranged to extend within the same plane perpendicular to the third lateral side and the second lateral side.

17. The semiconductor package according to claim 15, wherein the sealing resin further comprises one or more second extended portions that extend outward from the third lateral side and are arranged between the plurality of second leads.

18. The semiconductor package according to claim 15, further comprising one or more second reinforcement resins that extend outward from the third lateral side and are arranged between the plurality of second leads.

19. A semiconductor package, comprising:
a chip;
a sealing resin for sealing the chip, the sealing resin comprising a first lateral side and a second lateral side located adjacent to each other;
a plurality of first leads that protrude from different positions on the first lateral side, the positions on the first lateral side having different distances from the second lateral side, and the protruding distances of the plurality of first leads being set to be longer as the positions thereof on the first lateral side are located nearer to the second lateral side;
a plurality of second leads that protrude from different positions on a third lateral side that is located adjacent to the second lateral side and opposite to the first lateral side, the positions on the third lateral side having different distances from the second lateral side, and the protruding distances of the plurality of second leads being set to be longer as the positions thereof on the third lateral side are located nearer to the second lateral side; and
a mounting board that is electrically coupled to the plurality of first leads through conductive lines, and on which the second lateral side of the sealing resin in the chip is fixed.
